(19) United States
(12) Patent Application Publication
(10) Pub. No.: US 2025/0300079 A1
(43) Pub. Date: Sep. 25, 2025

(54) STIFFENER BETWEEN TWO SUBSTRATES

(71) Applicant: Intel Corporation, Santa Clara, CA (US)

(72) Inventors: Bok Eng CHEAH, Gelugor (MY); Seok Ling LIM, Bukit Mertajam (MY); Jenny Shio Yin ONG, Bayan Lepas (MY); Chin Lee KUAN, Pahang (MY); Jackson Chung Peng KONG, Tanjung Tokong (MY)

(21) Appl. No.: 18/615,182

(22) Filed: Mar. 25, 2024

(51) Int. Cl. H01L 23/528; H01L 23/00; H01L 23/498; H01L 23/66; H01L 25/16

(52) U.S. Cl. CPC H01L 23/5283; H01L 23/49816; H01L 23/5286; H01L 23/66; H01L 24/16; H01L 24/17; H01L 25/162; H01L 2224/16225; H01L 2224/1703; H01L 2224/17517

(57) ABSTRACT

Embodiments herein relate to systems, apparatuses, techniques, or processes directed to semiconductor packages that use a stiffener on a first substrate to secure a second substrate to the first substrate. The stiffener may include one or more compressible interconnects to electrically couple the first substrate and the second substrate. A fastener may extend through the second substrate and through the stiffener to secure the first substrate and the second substrate with each other. Other embodiments may be described and/or claimed.

### BACKGROUND

Continued reduction in end product size of mobile electronic devices such as smart phones and ultrabooks is a driving force for the development of reduced size system in package components.

### BRIEF DESCRIPTION OF THE DRAWINGS

FIGS. 1A-1B illustrate a cross-section side view and a prospective view of a legacy implementation of a compression connector to connect a memory substrate with the motherboard.

FIGS. 2A-2B illustrate a cross-section side view and a top-down view of a package that includes a stiffener between two substrates, in accordance with various embodiments.

FIG. 3 illustrates a top-down view of a stiffener and a top-down view of a substrate to which the stiffener is to be applied, in accordance with various embodiments.

FIG. 4 illustrates another cross-section side view of a package that includes a substrate with a stiffener applied, in accordance with various embodiments.

FIGS. 5A-5E illustrate stages in a manufacturing process for creating a package with a stiffener between two substrates, in accordance with various embodiments.

FIG. 6 illustrates an example of a process for creating a package with a stiffener between two substrates, in accordance with various embodiments.

FIG. 7 schematically illustrates a computing device, in accordance with embodiments.

### DETAILED DESCRIPTION

Embodiments of the present disclosure may generally relate to systems, apparatus, techniques, and/or processes directed to packages that use a stiffener on a first substrate to secure a second substrate to the first substrate. In embodiments, the first substrate may include one or more dies that may include processor dies such as a CPU or a system-on-chip (SOC). The second substrate may include memory to be accessed by the one or more dies, or may include other components such as power conditioning components that may be used by the one or more dies.

In embodiments, the stiffener may be on a top surface of the first substrate and extend down an edge of the first substrate. In embodiments, the stiffener may be physically coupled with or adjacent to a third substrate that is below the first substrate. In embodiments, a fastener, such as a screw, a bolt, or some other fastener, may extend from a first bolster plate on a top of the second substrate, through the second substrate, through a hole in the stiffener, through the third substrate, and to a second bolster plate at a bottom of the third substrate. The fastener may then be tightened, causing the second substrate to be compressed onto a top of the stiffener. In embodiments, the fastener may be loosened in order to remove the second substrate.

In embodiments, the stiffener may also include one or more electrical interconnects that extend through the stiffener and electrically couple with the first substrate. These electrical interconnects may include compressible interconnects, such as spring-loaded interconnects, pogo-pins, and/or compression pins. When the second substrate is placed and secured by the fastener to the first substrate, the second substrate and the first substrate may be electrically coupled through the one or more interconnects that extend through the stiffener. In embodiments, these electrical interconnects may carry signal, power, or ground reference voltage. In embodiments, the electrical interconnects may be electrically isolated from the stiffener. In embodiments, the stiffener may serve as a shield for the electrical interconnects. Other embodiments are discussed below.

In embodiments, the removable structure may be a detachable memory on package (MoP). In embodiments, this architecture may address electrical signaling bandwidth and power delivery constraints of a memory interface with legacy compression attached memory modules (CAMM) on a motherboard. These legacy implementations require excessive routing between a CPU/SOC and a CAMM connector due to the required assembly keep out zones (KOZ) that may lead to severe crosstalk coupling noises due to routing along the motherboard. In addition, legacy implementations may introduce multiple impedance discontinuities across the routing along the motherboard, and particularly with capacitive vertical structures and transitions that may lead to signal degradation that hinders memory data rate scaling beyond 10 Gbps.

As a result, legacy packages may be higher in power consumption and may require complex circuitry to compensate for signal degradation. For example, these legacy implementations may require equalization and/or crosstalk cancellation circuitry, such as: derivative crosstalk cancellation (DXC) or floating-tap decision feedback equalizer (DFE) for signal recovery, restriction of channel routing length landing zone, increased PCB shielding layer count for signal crosstalk mitigation. Other legacy implementations may use reduced package and platform interconnect geometry by using advanced manufacturing processes, for example ultra-thin core package or Type-4 PCB for improved impedance matching.

In embodiments, using stiffeners between substrates within a package may reduce the signal latency between the one or more processor dies and memory devices, such as DRAM memory modules, double data rate (DDR) memory modules, and/or lower power DDR (LPDDR) memory modules due to shorter and less distorted signal transmission paths by bringing the processor dies and memory devices in closer proximity. In addition, in embodiments, a more direct signal interconnect may exist between the processor and the multiple memory devices without any signal propagating through the lateral routing on a motherboard or PCB. As a result, signal crosstalk coupling may be reduced.

In embodiments, using stiffeners within a package may enhance the power delivery network by integrating power delivery components such as LC filters, inductors, and/or decoupling capacitors on a detachable substrate that may be dedicated for power delivery. The proximity of these power delivery components to the one or more dies and the memory devices may facilitate minimal voltage droop, thus resulting in more effective power delivery performance.

In embodiments, using stiffeners within a package may also facilitate smaller-sized packages through the integration of detachable substrates into the package stiffener structure. This may allow platform footprint reduction through elimination of PCB routing areas for power, and also result in PCB real estate savings by overlapping portions of the package substrate and the memory device components.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purpose of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

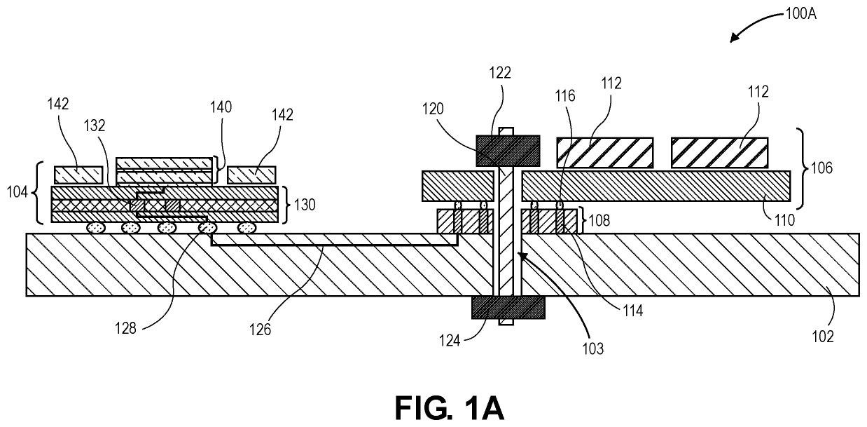

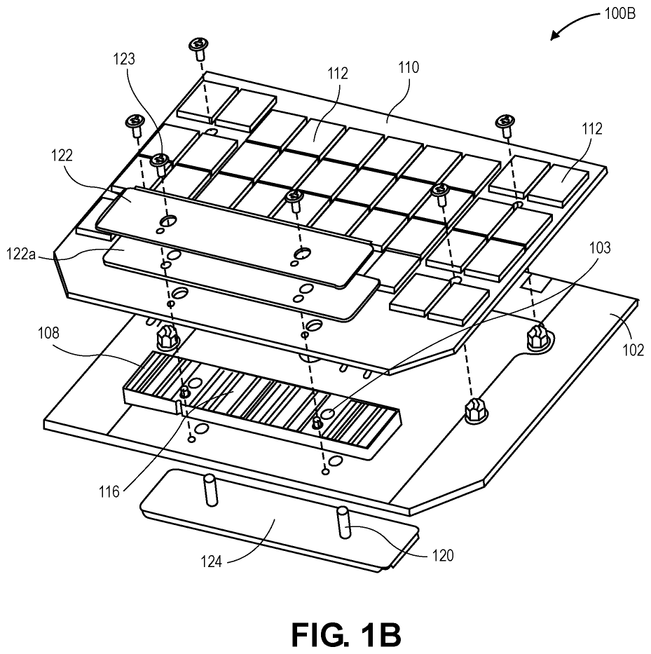

FIGS. 1A-1B illustrate a cross-section side view and a prospective view of a legacy implementation of a compression connector to connect a memory substrate with the motherboard. FIG. 1A shows a cross-section side view of a legacy package 100A that includes a motherboard 102, that includes a processor package 104 that is physically and electrically coupled to the motherboard 102, and a CAMM 106 that is coupled to the motherboard 102 using a compression connector 108.

In implementations, the CAMM 106 includes a memory substrate 110, with one or more memory devices 112 on the memory substrate 110. Note that in legacy implementations, the memory devices 112 may be configured on a top surface of the memory substrate 110. The memory devices may be coupled to the motherboard 102 through the compression connector 108 using electrically conductive compression pins 114 that include a protruded portion 116 for at least some of the compression pins 114.

In implementations, a fastener 120 may extend through the memory substrate 110, through the compression connector 108, and through the motherboard 102. The fastener 120 may include a screw or a bolt. A top bolster plate 122 may be at a top surface of the memory substrate 110, and a bottom bolster plate 124 may be at a bottom of the motherboard 102 through a mounting hole 103. In legacy implementations, one or more screws (not shown) may be used to tighten the fastener 120, thus compressing a bottom side of the memory substrate 110 to the compression connector 108.

In implementations, the compression pins 114 of the compression connector 108 may be electrically coupled through an electrical routing 126 within the motherboard 102 to a ball grid array 128 that is on a surface of the motherboard 102. In implementations, the ball grid array 128 may be electrically and physically coupled with the processor package 104.

In implementations, the processor package 104 includes a processor substrate 130 that includes one or more electrically conductive vias 132. One or more dies 140 may be on the processor substrate 130. In implementations, the one or more dies 140 may include CPUs and/or SOCs. In implementations, there may be one or more package stiffeners 142 on a surface of the processor substrate 130.

In implementations, a power source and/or power conditioning components (not shown) may be located on the motherboard and may provide power to the processor package 104 and/or the CAMM 106.

FIG. 1B shows an exploded prospective view of a legacy implementation of a legacy package 100B, which may be similar to the legacy package 100A shown in FIG. 1A. In implementations, a plurality of memory devices 112 may be on a memory substrate 110. A gasket 122a may be under a top bolster plate 122, which are both on the memory substrate 110.

A compression connector 108 may be on a surface of the motherboard 102, and include a plurality of compression pins, not shown but may be similar to compression pins 114 of FIG. 1A, that may electrically couple with the memory substrate 110. In implementations, mounting holes 103 may be within the motherboard 102, the compression connector 108, the gasket 122a and the top bolster plate 122. When assembled, the fasteners 120 may extend through the mounting holes 103 and up through the top bolster plate 122. Screws 123 may then be used to tighten the top bolster plate and the memory substrate to the compression connector 108, thus forming electrical connections between the memory substrate 110 and the motherboard 102.

In the legacy implementation of FIGS. 1A-1B, electrical signaling bandwidth and power delivery may be constrained between the processor substrate 130 and the memory substrate 110. In particular, the lengthy signal transmission path between them through electrical routing 126 due to mechanical keep out zone may result in severe crosstalk coupling noises, in addition to impedance discontinuities across the motherboard 102.

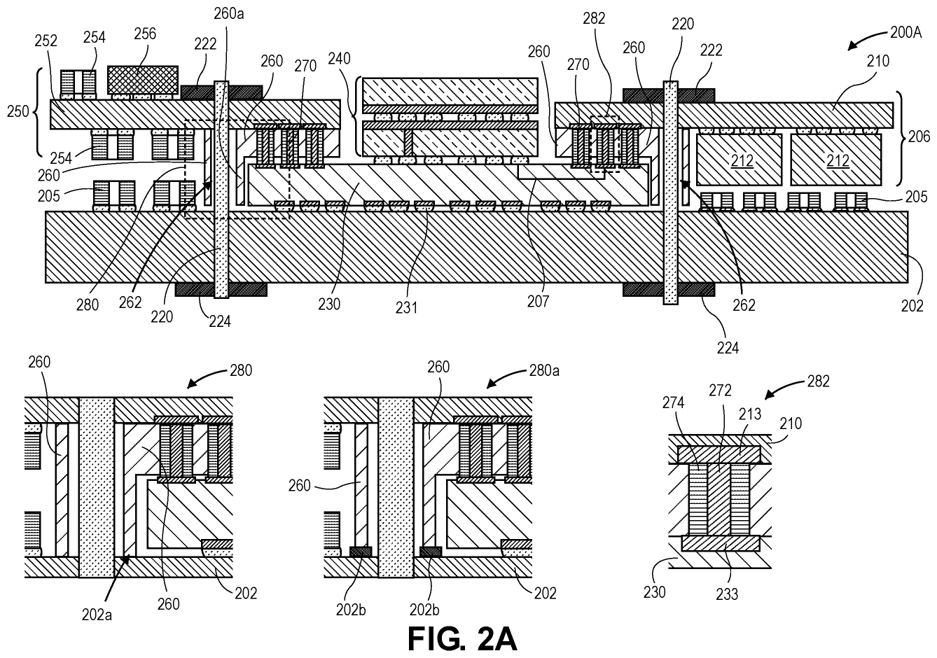

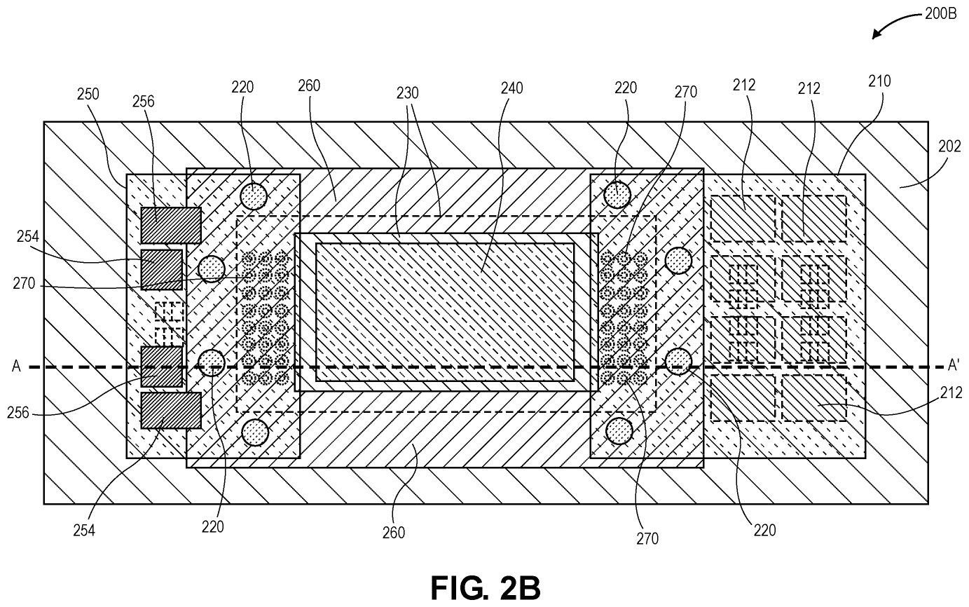

FIGS. 2A-2B illustrate a cross-section side view and a top-down view of a package that includes a stiffener between two substrates, in accordance with various embodiments. Package 200A shows a cross-section side view of a package that includes a printed circuit board (PCB) 202, which may be similar to the motherboard 102 of FIG. 1A. A processor substrate 230, which may be similar to processor substrate 130 of FIG. 1A, may be on and electrically coupled with the PCB 202 using bumps 231. In embodiments, other devices 205 may be on a surface of the PCB 202.

A one or more dies 240 may be on the processor substrate 230, and may be electrically coupled with each other and/or electrically coupled with the processor substrate 230 using bumps 231. In embodiments, the one or more dies 240 may include CPU devices, SOC devices, graphics processing unit (GPU) devices, field programmable gate array (FPGA) devices, deep learning processor (DLP) devices, neural network processor (NNP) devices, or some other computational device.

In embodiments, a stiffener 260 may be at least partially on the processor substrate 230. A portion of the stiffener 260a may extend down an edge of the processor substrate 230. In embodiments, the edge of the processor substrate 230 may be orthogonal to a surface of the processor substrate 230. In embodiments, a portion of the stiffener 260a may extend to the PCB 202. In embodiments, the stiffener 260 may include one or more metal layers, and in embodiments the metal layers may be associated with a reference voltage, for example a ground reference voltage (VSS) to provide shielding to compressible interconnects 270. In embodiments, the stiffener 260 may include aluminum, stainless steel, and/or some other electrically conductive component. In embodiments, the stiffener 260 may include one or more sheets of electrically conductive material. In embodiments, the stiffener 260 may include non-electrically conductive material and/or layers, such as, but not limited to, organic mold epoxy, a polycarbonate, an acrylonitrile butadiene styrene (ABS) and/or ceramic material. In embodiments, an adhesive comprises a thermal curable acrylate, an epoxy polymer, a polyimide, a polyamide, a polyurethane, a polyester or an acrylic polymer (not shown) may be used to secure the stiffener 260 to the processor substrate 230.

In embodiments, the stiffener 260 may include one or more openings 262, through which fasteners 220, which may be similar to fasteners 120 of FIG. 1A, may be inserted. As shown in diagram 280, which is a magnified portion 280 of package 200A, in embodiments, a portion of the stiffener 260 may extend all the way to a top portion of the PCB 202a. In alternative embodiments, as shown in diagram 280a, a portion of the stiffener 260 may extend to a pad 202b that may be placed on a surface of the PCB 202.

In embodiments, compressible interconnects 270, which may be referred to as through-stiffener interconnects, may be inserted into or through part of the stiffener 260. In embodiments, the compressible interconnects 270 may provide an electrical coupling between a top of the stiffener 260 and a top surface of the processor substrate 230. In embodiments, the compressible interconnects 270 may take a variety of forms, including but not limited to spring-loaded interconnects, pogo-pins, and/or compression pins. In embodiments, a portion of the compressible interconnects 270 may extend beyond a bottom of the stiffener when the stiffener 260 is not attached on the top surface of the processor substrate 230.

Diagram 282, which is a magnified portion 282 of package 200A, shows an example of a compressible interconnect 270 that includes an internal conductive core 272, which may include copper, that is surrounded by a dielectric 274. In embodiments, the dielectric 274 may include an air gap, a plastic housing, or some other dielectric material. In embodiments, the compressible interconnects 270, from a top view, may be a circular, oval, oblong, rectangular, or some other shape. In embodiments, a portion of the compressible interconnect 270 may extend beyond a bottom of the stiffener when the stiffener 260 is not attached on the top surface of the processor substrate 230.

In embodiments, a second portion of the compressible interconnects 270 may extend beyond the top of the stiffener 260 when the memory substrate 210 is not attached on the top of the stiffener 260. In embodiments, the compressible interconnects 270 may electrically couple with a pad 213 that may be within the memory substrate 210, and may electrically couple with a pad 233 that may be on a surface of the processor substrate 230. In embodiments, the memory package 206 may electrically couple with the one or more dies 240 using a routing 207 within the processor substrate 230. In embodiments, signals between the memory package 206 and the one or more dies 240 may not go through the PCB 202.

In embodiments, the compressible interconnects 270 may be electrically coupled with a memory package 206, which may be similar to the CAMM 106 of FIG. 1A. In embodiments, the memory package 206 may be referred to as a detachable memory on package (MoP). In particular, the compressible interconnects 270 may be electrically coupled with a memory substrate 210, which may be similar to memory substrate 110 of FIG. 1A, and may contain memory devices 212, which may be similar to memory devices 112 of FIG. 1A.

Similarly, in embodiments, the compressible interconnects 270 may be electrically coupled with a power package 250, which may include a power substrate 252. In embodiments, the power substrate 252 may include and may be electrically coupled with one or more passive components, for example but not limited to capacitors 254 and LC filters 256. In embodiments, the power package 250 may receive power from the PCB through one or more of the compressible interconnects 270, condition the power, and then send the condition power back through one or more of the compressible interconnects 270 to the processor substrate 230 to provide power to the one or more dies 240.

In embodiments, one or more fasteners 220, which may be similar to fasteners 120 of FIG. 1A, may be inserted into one or more openings 262. In embodiments, the fasteners 220 may extend through the PCB 202, and may extend through the memory substrate 210 or the power substrate 252. In embodiments, bottom bolster plates 224 and top bolster plates 222 may be physically coupled with the fasteners 220. In embodiments, the bolster plates may be referred to as supporting plates. In embodiments, the fastener 220 may be tightened in order to compress the memory substrate 210 or the power substrate 252 onto the compressible interconnects 270 within the stiffener 260. In embodiments, the fasteners 220 may be bolts with nuts on one or both ends. In embodiments, the fasteners 220 may be screws. In embodiments, the fasteners 220 may be some other method of securing the memory substrate 210 or the power substrate 252 onto the compressible interconnects 270.

Although the memory package 206 and the power package 250 were discussed above with respect to their connections with the compressible interconnects 270, it should be appreciated that any type of packages, for example a plurality of memory packages 206, or other packages that may have other functions or features with respect to the configuration and/or operation of the package 200A may be used in the various other embodiments. Furthermore, although the power package 250 and the memory package 206 are shown as opposing each other, the power package 250 and the memory package 206, as well as any other removable packages (not shown) may be positioned in any direction relative to the processor substrate 230 depending upon the configuration and/or number of stiffeners 260.

In embodiments, the architecture of the package 200A may support decreased channel loss and loop inductance, and may increase the channel voltage and timing margin when compared to legacy implementations. In addition, the L-shape of the stiffener 260 may also improve warpage control of the package 200A.

FIG. 2B shows a top-down view of package 200B, which may be similar to package 200A of FIG. 2A. For reference, package 200A is a cross-section side view at A-A′ of FIG. 2B. Processor substrate 230 is on PCB 202, and is partially obscured by stiffener 260. Power substrate 252, that includes LC filters 256 and capacitors 254, may be on a portion of the stiffener 260, and may be electrically coupled with one or more of the compressible interconnects 270. In embodiments, the power substrate 252 is secured to the stiffener 260 and to the PCB 202 using a plurality of fasteners 220 and bolster plates (not shown). In embodiments, the power substrate 252 may also include inductors, and/or decoupling capacitors to facilitate power delivery.

Similarly, memory substrate 210 that includes memory devices 212 may be on a portion of the stiffener 260, and may be electrically coupled with one or more of the compressible interconnects 270. In embodiments, the memory substrate 210 is secured to the stiffener 260 and to the PCB 202 using a plurality of fasteners 220 and bolster plates (not shown). Note that the memory devices 212 are shown on a bottom of the memory substrate 210. In other embodiments, the memory devices 212 may be on a top of the memory substrate 210.

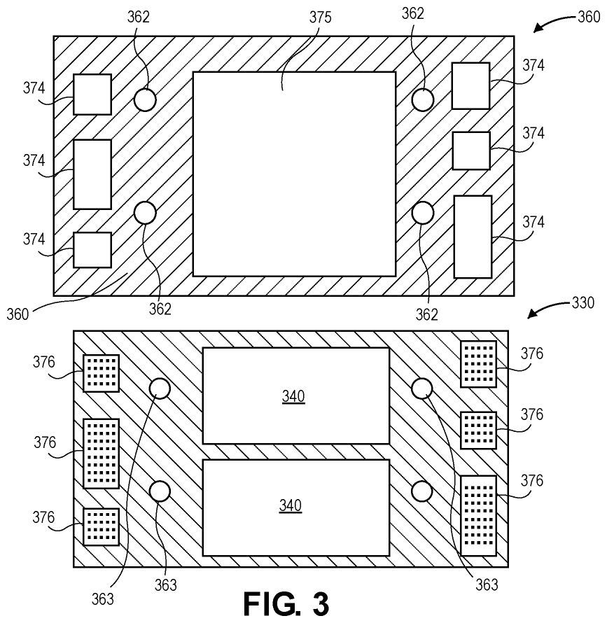

FIG. 3 illustrates a top-down view of a stiffener and a top-down view of a substrate to which the stiffener is to be applied, in accordance with various embodiments. FIG. 3 shows a different embodiment as compared to FIGS. 2A-2B. In embodiments, processor substrate 330, which may be similar to processor substrate 230 of FIG. 2A, may include one or more processors 340, which may be similar to one or more dies 240 of FIG. 2A. In embodiments, processor substrate 330 may also include a plurality of sockets 376 that may extend upward from the processor substrate 330. In embodiments, openings 363 may exist within the processor substrate 330, through which fasteners, for example fasteners 220 of FIG. 2B, may be inserted.

In embodiments, stiffener 360, which may be similar to stiffener 260 of FIG. 2B, may include a plurality of holes 374 that extend through the stiffener 360 and are aligned with the plurality of sockets 376 on processor substrate 330. In addition, openings 362 may be aligned with openings 363 such that fasteners, such as fasteners 220 of FIG. 2B, may pass through both the openings 362 and openings 363. An opening 375 may be aligned with the one or more processors 340, such that the one or more processors 340 will be at least partially within the opening 375 when the stiffener 360 is placed on the processor substrate 330. In this embodiment, contact pads (not shown) that may be on the power substrate 252 or the memory substrate 210 of FIG. 2B, when placed on the stiffener 360 will properly seat with the plurality of sockets 376 when the fasteners, which may be similar to fasteners 220 of FIG. 2B, are secured. In embodiments, an adhesive may comprise a thermal curable acrylate, an epoxy polymer, a polyimide, a polyamide, a polyurethane, a polyester or an acrylic polymer (not shown) and may be used to secure the plurality of sockets 376 to the top of the processor substrate 330.

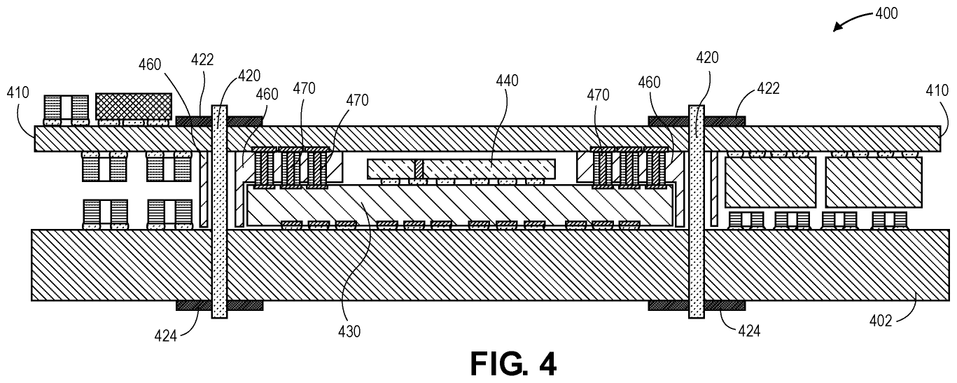

FIG. 4 illustrates another cross-section side view of a package that includes a substrate with a stiffener applied, in accordance with various embodiments. Package 400, which may be similar to package 200A of FIG. 2A, includes a stiffener 460 that is on a processor substrate 430, where both the stiffener 460 and the processor substrate 430 are on a PCB 402. PCB 402, processor substrate 430, and stiffener 460 may be similar to PCB 202, processor substrate 230, and stiffener 260 of FIG. 2A. In embodiments, compressible interconnects 470, which may be similar to compressible interconnects 270 of FIG. 2A, may extend through the stiffener 460 and electrically couple with the processor substrate 430.

In embodiments, a single substrate 410, which may be similar to power substrate 252 or to memory substrate 210 of FIG. 2A, may extend across the processor substrate 430, and may be electrically coupled with the compressible interconnects 470 to electrically couple the processor substrate 430 with the single substrate 410. In embodiments, fasteners 420 may extend through the single substrate 410, through holes in the stiffener 460, and holes in the PCB 402. The fasteners 420 may be secured by top bolster plates 422 and bottom bolster plates 424, which may be similar to top bolster plates 222 and bottom bolster plates 224 of FIG. 2A. In embodiments, the single substrate 410 may include one or more openings to accommodate one or more dies 440 on a top of the processor substrate 430.

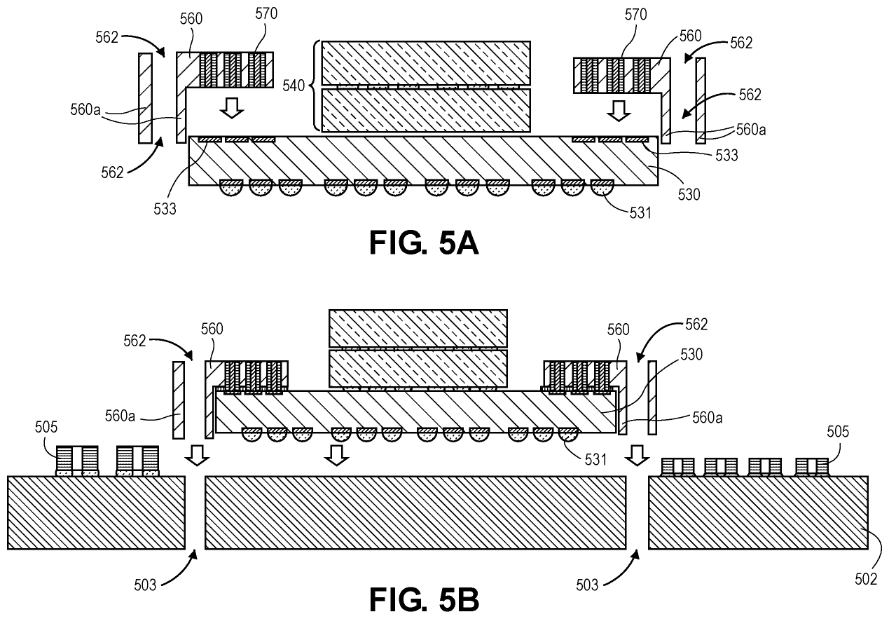

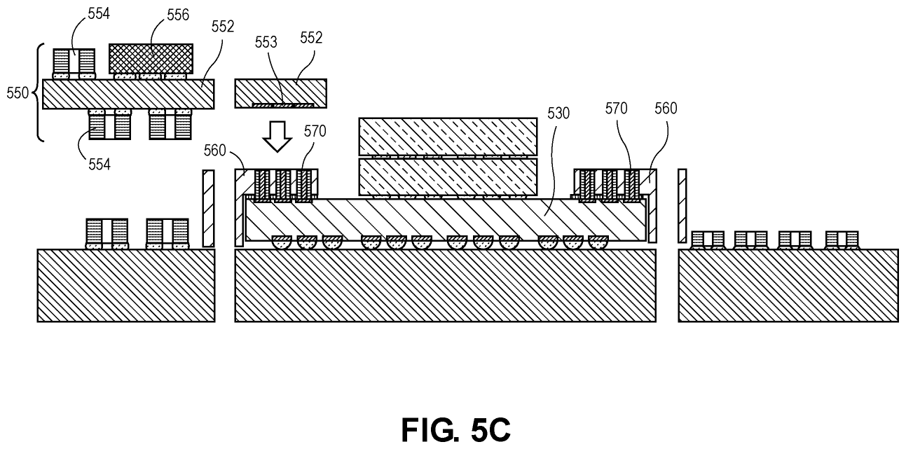

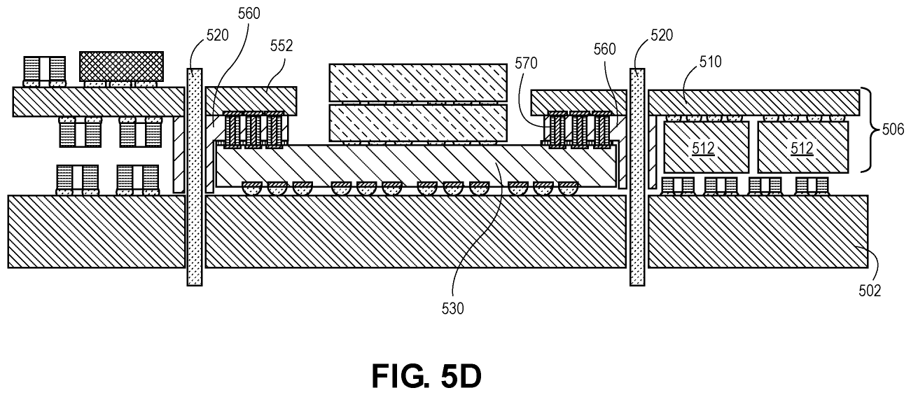

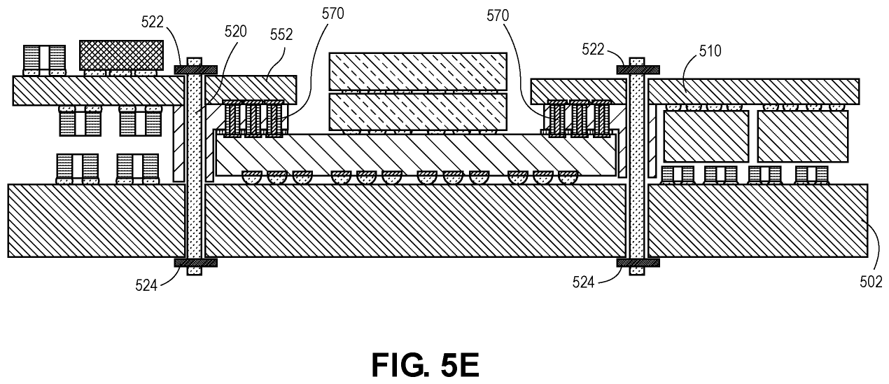

FIGS. 5A-5E illustrates stages in a manufacturing process for creating a package with a stiffener between two substrates, in accordance with various embodiments. FIG. 5A shows a cross-section side view of a stage in the manufacturing process where a processor substrate 530, which may be similar processor substrate 230 of FIG. 2A, may be provided. In embodiments, bumps 531 may be on a bottom of the processor substrate 530 that electrically couple with the processor substrate 530, and pads 533 may be on a top of the processor substrate 530.

In embodiments, a stiffener 560, which may be similar to stiffener 260 of FIG. 2A, may be placed on the top of the processor substrate 530, with a portion of the stiffener 560a extending down an edge of the processor substrate 530. In embodiments, compressible interconnects 570, which may be similar to compressible interconnects 270 of FIG. 2A, may be within the stiffener 560. In embodiments, openings 562, which may be similar to openings 262 of FIG. 2A, may extend through the stiffener 560.

When assembled, the compressible interconnects 570 may be electrically coupled with the pads 533. In embodiments, the one or more dies 540, which may be similar to one or more dies 240 of FIG. 2A, may be on the top of the processor substrate 530. In embodiments, an adhesive may comprise a thermal curable acrylate, an epoxy polymer, a polyimide, a polyamide, a polyurethane, a polyester or an acrylic polymer (not shown) and may be used to secure the stiffener 560 to the top of the processor substrate 530.

FIG. 5B shows a cross-section side view of a stage in the manufacturing process where a PCB 502 is provided. In embodiments, the PCB 502 may be similar to PCB 202 of FIG. 2A. In embodiments, the PCB 502 may be any other substrate or device to which the partial package shown in FIG. 5A may be attached. In embodiments, the PCB 502 may include one or more components 505 on a surface of the PCB 502. In embodiments, the components 505 may be active and/or passive components. In embodiments, mounting holes 503 may extend through the PCB 502. In embodiments, the processor substrate 530 and the bumps 531 may come into electrical and physical contact with a portion of the PCB 502, for example, one or more contact pads of the PCB 502 (not shown). In embodiments, a bottom portion of the stiffener 560a may come into contact with the PCB 502.

FIG. 5C shows a cross-section side view of a stage in the manufacturing process where a power package 550, which may be similar to power package 250 of FIG. 2A, may be assembled. In embodiments, the power package 550 may include a power substrate 552, which may be physically and/or electrically coupled with capacitors 554 and LC filters 556, which may be similar to power substrate 252, capacitors 254, and LC filters 256 of FIG. 2A. In embodiments, pads 553 may be on the bottom of the power substrate 552.

In embodiments, the pads 553 may electrically couple with the compressible interconnects 570 within the stiffener 560. As a result, the power package 550 may be electrically coupled with the processor substrate 530.

FIG. 5D shows a cross-section side view of a stage in the manufacturing process where a memory package 506, which may be similar to memory package 206 of FIG. 2A, may be placed onto the stiffener 560 and the electrically coupled with the compressible interconnects 570 to electrically couple with the processor substrate 530. The memory package 506 may include memory devices 512, which may be similar to memory devices 212 of FIG. 2A.

In embodiments, fasteners 520, which may be similar to fasteners 220 of FIG. 2A, may be inserted through the memory substrate 510, power substrate 552, stiffener 560, and PCB 502.

FIG. 5E shows a cross-section side view of a stage in the manufacturing process where top bolster plates 522 and bottom bolster plates 524 are placed on each of the fasteners 520. In embodiments, they may be tightened in order to compress the memory substrate 510 and the power substrate 552 onto the compressible interconnects 570.

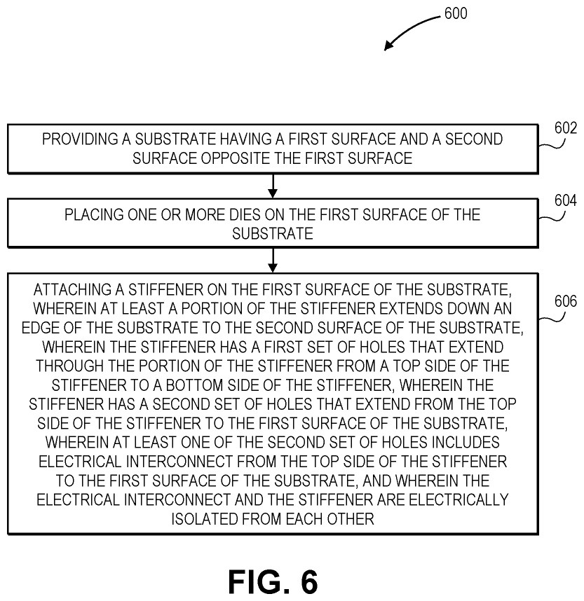

FIG. 6 illustrates an example of a process for creating a package with a stiffener between two substrates, in accordance with various embodiments. Process 600 may be performed by the elements, techniques, processes, or systems that may be described herein, and in particular with respect to FIGS. 2A-5E.

At block 602, the process may include providing a substrate having a first surface and a second surface opposite the first surface. In embodiments, the substrate may be similar to the processor substrate 230 of FIGS. 2A-2B, processor substrate 330 of FIG. 3, processor substrate 430 of FIG. 4, and processor substrate 530 of FIGS. 5A-5E. In embodiments, the substrate may be any substrate, or in embodiments the substrate may be any other component or other device, such as a block die. In embodiments, the substrate may comprise a silicon substrate, a glass substrate, an organic substrate or a ceramic substrate.

At block 604, the process may further include placing one or more dies on the first surface of the substrate. In embodiments, the one or more dies may be similar to one or more dies 240 of FIGS. 2A-2B, dies 340 of FIG. 3, dies 440 of FIG. 4, or one or more dies 540 of FIGS. 5A-5E.

At block 606, the process may further include attaching a stiffener on the first surface of the substrate, wherein at least a portion of the stiffener extends down an edge of the substrate to the second surface of the substrate, wherein the stiffener has a first set of holes that extend through the portion of the stiffener from a top side of the stiffener to a bottom side of the stiffener, wherein the stiffener has a second set of holes that extend from the top side of the stiffener to the first surface of the substrate, wherein at least one of the second set of holes includes electrical interconnect from the top side of the stiffener to the first surface of the substrate, and wherein the electrical interconnect and the stiffener are electrically isolated from each other.

In embodiments, the stiffener may be similar to stiffener 260 of FIGS. 2A-2B, stiffener 360 of FIG. 3, stiffener 460 of FIG. 4, or stiffener 560 of FIGS. 5A-5E. In embodiments, the stiffener may be a plurality of stiffener that may be attached to the first surface of the substrate. In embodiments, the first set of holes may be similar to openings 262 of FIG. 2A, openings 362 of FIG. 3, or openings 562 of FIGS. 5A-5B. In embodiments, the second set of holes may be similar to the holes into which compressible interconnects 270 of FIGS. 2A-2B are inserted, holes 374 of FIG. 3, holes into which compressible interconnects 470 of FIG. 4 are inserted, or holes into which compressible interconnects 570 of FIGS. 5A-5E are inserted.

In embodiments, the electrical interconnect may be similar to compressible interconnects 270 of FIGS. 2A-2B, sockets 376 of FIG. 3, compressible interconnects 470 of FIG. 4, or compressible interconnects 570 of FIG. 5A.

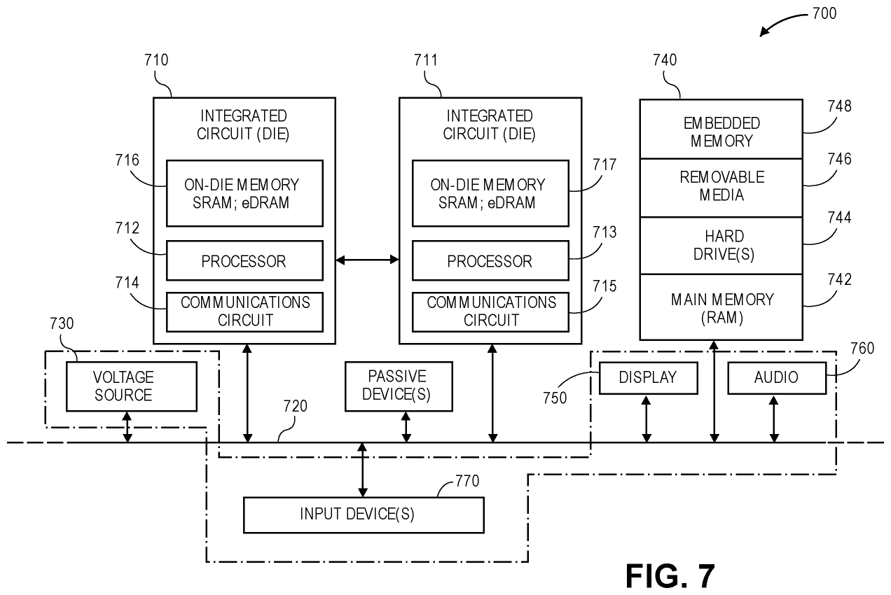

FIG. 7 is a schematic of a computer system 700, in accordance with an embodiment of the present invention. The computer system 700 (also referred to as the electronic system 700) as depicted can embody a stiffener between two substrates, according to any of the several disclosed embodiments and their equivalents as set forth in this disclosure. The computer system 700 may be a mobile device such as a netbook computer. The computer system 700 may be a mobile device such as a wireless smart phone. The computer system 700 may be a desktop computer. The computer system 700 may be a hand-held reader. The computer system 700 may be a server system. The computer system 700 may be a supercomputer or high-performance computing system.

In an embodiment, the electronic system 700 is a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In some embodiments, the voltage source 730 supplies current to the integrated circuit 710 through the system bus 720.

The integrated circuit 710 is electrically coupled to the system bus 720 and includes any circuit, or combination of circuits according to an embodiment. In an embodiment, the integrated circuit 710 includes a processor 712 that can be of any type. As used herein, the processor 712 may mean any type of circuit such as, but not limited to, a microprocessor, a microcontroller, a graphics processor, a digital signal processor, or another processor. In an embodiment, the processor 712 includes, or is coupled with, a stiffener between two substrates, as disclosed herein. In an embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM).

In an embodiment, the integrated circuit 710 is complemented with a subsequent integrated circuit 711. Useful embodiments include a dual processor 713 and a dual communications circuit 715 and dual on-die memory 717 such as SRAM. In an embodiment, the dual integrated circuit 710 includes embedded on-die memory 717 such as eDRAM.

In an embodiment, the electronic system 700 also includes an external memory 740 that in turn may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also be embedded memory 748 such as the first die in a die stack, according to an embodiment.

In an embodiment, the electronic system 700 also includes a display device 750, an audio output 760. In an embodiment, the electronic system 700 includes an input device such as a controller 770 that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

As shown herein, the integrated circuit 710 can be implemented in a number of different embodiments, including a package substrate having a stiffener between two substrates, according to any of the several disclosed embodiments and their equivalents, an electronic system, a computer system, one or more methods of fabricating an integrated circuit, and one or more methods of fabricating an electronic assembly that includes a package substrate having a stiffener between two substrates, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a stiffener between two substrates embodiments and their equivalents. A foundation substrate may be included, as represented by the dashed line of FIG. 7. Passive devices may also be included, as is also depicted in FIG. 7.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

### EXAMPLES

The following paragraphs describe examples of various embodiments.

Example 1 is an apparatus comprising: a substrate with a first surface and a second surface opposite the first surface; and a stiffener on the first surface of the substrate, wherein a portion of the stiffener extends down an edge of the substrate to the second surface of the substrate, wherein the stiffener includes one or more holes that extend through the portion of the stiffener, and wherein the one or more holes are substantially perpendicular to the first surface of the substrate.

Example 2 includes the apparatus example 1, wherein the one or more holes is a first set of one or more holes; and further comprising a second set of one or more holes, wherein the second set of one or more holes extend from a top of the stiffener to the first surface of the substrate, and wherein the first set of one or more holes have a long axis that is within 3 degrees of a plane of the first surface of the substrate.

Example 3 includes the apparatus of example 2, wherein at least one of the second set of one or more holes includes an electrical interconnect.

Example 4 includes the apparatus of example 3, wherein the electrical interconnect further comprises a selected one or more of: a compressible structure, a spring-loaded interconnect, or a compression pin.

Example 5 includes the apparatus of examples 3 or 4, wherein the electrical interconnect and the stiffener are electrically isolated from each other.

Example 6 includes the apparatus of examples 2, 3, 4, or 5, further comprising a socket on the first surface of the substrate, wherein the socket is electrically coupled with the substrate, and wherein the socket is at least partially within one of the second set of one or more holes.

Example 7 includes the apparatus of examples 1, 2, 3, 4, 5, or 6, wherein the edge of the substrate is a first edge, and wherein the portion of the stiffener is a first portion; and wherein a second portion of the stiffener extends down a second edge of the substrate to the second surface of the substrate.

Example 8 includes the apparatus example 7, wherein the second portion of the stiffener comprises one or more holes that extend from a top of the stiffener to the second surface of the substrate.

Example 9 includes the apparatus of examples 1, 2, 3, 4, 5, 6, 7, or 8, wherein the stiffener includes a selected one or more of: a metal layer, aluminum, stainless steel, a non-electrically conductive material, an organic mold epoxy, a polycarbonate, an acrylonitrile butadiene styrene (ABS) and/or a ceramic.

Example 10 includes the apparatus of examples 1, 2, 3, 4, 5, 6, 7, 8, or 9, wherein the portion of the stiffener extends below a bottom surface of the substrate.

Example 11 includes a package comprising: a first substrate; a second substrate on the first substrate, wherein the second substrate has a first surface and a second surface opposite the first surface; a stiffener on the first surface of the second substrate, wherein a portion of the stiffener extends down at least one edge of the second substrate to the second surface of the second substrate, wherein the stiffener includes a first set of one or more holes that extend from a first surface of the stiffener to a second surface of the stiffener opposite the first surface of the stiffener; and a second set of one or more holes, wherein the second set of one or more holes extend from a top of the stiffener to the first surface of the second substrate.

Example 12 includes the package of example 11, wherein at least one of the second set of one or more holes includes at least a portion of an electrical interconnect, wherein the electrical interconnect electrically couples with the second substrate.

Example 13 includes a package of example 12, further comprising: a third substrate on the stiffener, wherein the third substrate is electrically coupled with the electrical interconnect.

Example 14 includes the package of example 13, further comprising a fastener that is physically coupled with the third substrate and physically coupled with the first substrate, wherein the fastener passes through one of the first set of one or more holes.

Example 15 includes a package of example 14, wherein the fastener passes through the first substrate and the third substrate.

Example 16 includes a package of examples 13, 14, or 15, wherein the third substrate includes one or more components on a surface of the third substrate, wherein the one or more components are a selected one or more of: DDR memory, LPDDR memory, Neural Network Processor (NPU), LC filters, capacitors, and/or inductors.

Example 17 includes a package of examples 11, 12, 13, 14, 15, or 16, wherein the portion of the stiffener extends to a surface of the first substrate.

Example 18 includes the package of examples 11, 12, 13, 14, 15, 16, or 17, wherein the stiffener includes a selected one or more of: a metal layer, aluminum, stainless steel, a non-electrically conductive material, an organic mold epoxy, a polycarbonate, an acrylonitrile butadiene styrene (ABS), and/or a ceramic.

Example 19 is a method comprising: providing a substrate having a first surface and a second surface opposite the first surface; placing one or more dies on the first surface of the substrate; and attaching a stiffener on the first surface of the substrate, wherein at least a portion of the stiffener extends down an edge of the substrate to the second surface of the substrate, wherein the stiffener has a first set of holes that extend through the portion of the stiffener from a top side of the stiffener to a bottom side of the stiffener, wherein the stiffener has a second set of holes that extend from the top side of the stiffener to the first surface of the substrate, wherein at least one of the second set of holes includes electrical interconnect from the top side of the stiffener to the first surface of the substrate, and wherein the electrical interconnect and the stiffener are electrically isolated from each other.

Example 20 includes a method of example 19, wherein the substrate is a first substrate; and further comprising: providing a second substrate; attaching the first substrate to the second substrate, wherein the first substrate and the second substrate are physically and electrically coupled; providing a third substrate; attaching the third substrate to the top side of the stiffener, wherein the third substrate and the first substrate are electrically coupled through the electrical interconnect; providing a fastener; and physically coupling the third substrate, the first substrate, and the second substrate to each other with the fastener, wherein the fastener passes through one of the first set of holes that extend through the portion of the stiffener.

What is claimed is:

1. An apparatus comprising:
a substrate with a first surface and a second surface opposite the first surface; and
a stiffener on the first surface of the substrate, wherein a portion of the stiffener extends down an edge of the substrate to the second surface of the substrate, wherein the stiffener includes one or more holes that extend through the portion of the stiffener, and wherein the one or more holes are substantially perpendicular to the first surface of the substrate.

2. The apparatus of claim 1, wherein the one or more holes is a first set of one or more holes; and further comprising a second set of one or more holes, wherein the second set of one or more holes extend from a top of the stiffener to the first surface of the substrate, and wherein the first set of one or more holes have a long axis that is within 3 degrees of a plane of the first surface of the substrate.

3. The apparatus of claim 2, wherein at least one of the second set of one or more holes includes an electrical interconnect.

4. The apparatus of claim 3, wherein the electrical interconnect further comprises a selected one or more of:
a compressible structure, a spring-loaded interconnect, or a compression pin.

5. The apparatus of claim 3, wherein the electrical interconnect and the stiffener are electrically isolated from each other.

6. The apparatus of claim 2, further comprising a socket on the first surface of the substrate, wherein the socket is electrically coupled with the substrate, and wherein the socket is at least partially within one of the second set of one or more holes.

7. The apparatus of claim 1, wherein the edge of the substrate is a first edge, and wherein the portion of the stiffener is a first portion; and wherein a second portion of the stiffener extends down a second edge of the substrate to the second surface of the substrate.

8. The apparatus of claim 7, wherein the second portion of the stiffener comprises one or more holes that extend from a top of the stiffener to the second surface of the substrate.

9. The apparatus of claim 1, wherein the stiffener includes a selected one or more of:
a metal layer, aluminum, stainless steel, a non-electrically conductive material, an organic mold epoxy, a polycarbonate, an acrylonitrile butadiene styrene (ABS) and/or a ceramic.

10. The apparatus of claim 1, wherein the portion of the stiffener extends below a bottom surface of the substrate.

11. A package comprising:
a first substrate;
a second substrate on the first substrate, wherein the second substrate has a first surface and a second surface opposite the first surface;
a stiffener on the first surface of the second substrate, wherein a portion of the stiffener extends down at least one edge of the second substrate to the second surface of the second substrate, wherein the stiffener includes a first set of one or more holes that extend from a first surface of the stiffener to a second surface of the stiffener opposite the first surface of the stiffener; and
a second set of one or more holes, wherein the second set of one or more holes extend from a top of the stiffener to the first surface of the second substrate.

12. The package of claim 11, wherein at least one of the second set of one or more holes includes at least a portion of an electrical interconnect, wherein the electrical interconnect electrically couples with the second substrate.

13. The package of claim 12, further comprising: a third substrate on the stiffener, wherein the third substrate is electrically coupled with the electrical interconnect.

14. The package of claim 13, further comprising a fastener that is physically coupled with the third substrate and physically coupled with the first substrate, wherein the fastener passes through one of the first set of one or more holes.

15. The package of claim 14, wherein the fastener passes through the first substrate and the third substrate.

16. The package of claim 13, wherein the third substrate includes one or more components on a surface of the third substrate, wherein the one or more components are a selected one or more of: DDR memory, LPDDR memory, Neural Network Processor (NPU), LC filters, capacitors, and/or inductors.

17. The package of claim 11, wherein the portion of the stiffener extends to a surface of the first substrate.

18. The package of claim 11, wherein the stiffener includes a selected one or more of:
a metal layer, aluminum, stainless steel, a non-electrically conductive material, an organic mold epoxy, a polycarbonate, an acrylonitrile butadiene styrene (ABS), and/or a ceramic.

19. A method comprising:
providing a substrate having a first surface and a second surface opposite the first surface;
placing one or more dies on the first surface of the substrate; and
attaching a stiffener on the first surface of the substrate, wherein at least a portion of the stiffener extends down an edge of the substrate to the second surface of the substrate, wherein the stiffener has a first set of holes that extend through the portion of the stiffener from a top side of the stiffener to a bottom side of the stiffener, wherein the stiffener has a second set of holes that extend from the top side of the stiffener to the first surface of the substrate, wherein at least one of the second set of holes includes electrical interconnect from the top side of the stiffener to the first surface of the substrate, and wherein the electrical interconnect and the stiffener are isolated from each other.

20. The method of claim 19, wherein the substrate is a first substrate; and further comprising:
providing a second substrate;
attaching the first substrate to the second substrate, wherein the first substrate and the second substrate are physically and electrically coupled;
providing a third substrate;
attaching the third substrate to the top side of the stiffener, wherein the third substrate and the first substrate are electrically coupled through the electrical interconnect;
providing a fastener; and
physically coupling the third substrate, the first substrate, and the second substrate to each other with the fastener, wherein the fastener passes through one of the first set of holes that extend through the portion of the stiffener.
